(19) United States
(12) Patent Application Publication
(10) Pub. No.: US 2012/0047686 A1
(43) Pub. Date: Mar. 1, 2012

(54) Method and Apparatus for a Mechanical Joining

(75) Inventors: Mika Antero Hautamaki, Vesilahti (FI); Timo Vilho Juhani Herranen, Viiala (FI)

(73) Assignee: NOKIA CORPORATION, Espoo (FI)

(21) Appl. No.: 12/871,608

(22) Filed: Aug. 30, 2010

(51) Int. Cl. E05D 3/14; H05K 5/03

(52) U.S. Cl. 16/366

(57) ABSTRACT

The present application relates generally to joining two parts mechanically such that movement of the two parts relative to each other is enabled.

In accordance with an example embodiment of the present invention, a joint mechanism is configured to connect two apparatus portions. The joint mechanism comprises a main arm and a control arm configured to be connected to a first apparatus portion at their one pivot points, and configured to be connected to a second apparatus portion at their other pivot points. The pivot points are configured to enable movable connection between the two apparatus portions, and at least one of the pivot points comprises a movable pivot point.

### TECHNICAL FIELD

The present application relates generally to joining two parts mechanically such that movement of the two parts relative to each other is enabled.

### BACKGROUND

A mobile electronic apparatus need to have good usability and a compact structure. Usability may relate to a size of a user interface. Responding to both the usability and size, apparatuses having two parts have been introduced. Generally an apparatus may have a closed position, in which the two parts are in a compact, concise arrangement, close to each other. Further the apparatus may have an open position, in which the two parts are in an expanded, wide arrangement, moved apart from each others.

One example of a mobile electronic apparatus is a mobile phone comprising two parts movable relative to each other. The joining construction may be implemented utilizing rotatable, slide or tilt type of movement, for example. In a closed position the apparatus has a compact structure. In an open position the usability may be enhanced by an expanded user interface.

### SUMMARY

Various aspects of examples of the invention are set out in the claims. According to a first aspect of the present invention a joint mechanism comprises a main arm and a control arm. The main arm and the control arm comprise pivot points configured to be connectable to an apparatus. The pivot points are configured to enable movable connection between moving apparatus parts, and at least one of the pivot points comprises a movable pivot point.

According to a second aspect of the present invention an apparatus comprises at least two apparatus portions and a joint mechanism. The joint mechanism comprises a main arm and a control arm comprising pivot points. The main arm and the control arm are configured to be connected to a first apparatus portion at their one pivot points, and to a second apparatus portion at their other pivot points. The pivot points are configured to enable movable connection between the two apparatus portions. At least one of the pivot points comprises a movable pivot point.

According to a third aspect of the present invention a method comprises movably joining a first apparatus portion and a second apparatus portion of an apparatus by a joint mechanism. The the joint mechanism comprises main arm and a control arm connectable to the first apparatus portion on their one pivot points, and to the second apparatus portion on their other pivot points for enabling movable connection between the first and the second apparatus portions. At least one of the pivot points comprises a movable pivot point.

### BRIEF DESCRIPTION OF THE DRAWINGS

For a more complete understanding of example embodiments of the present invention, reference is now made to the following descriptions taken in connection with the accompanying drawings in which:

FIG. 1a illustrates an example of a two part apparatus according to an embodiment of the present invention in a closed position;

FIG. 1b illustrates an example of a two part apparatus according to an embodiment of the present invention in an open position;

FIG. 1c illustrates a side view of an example two part apparatus according to an embodiment of the present invention in an intermediate position.

FIG. 2a illustrates a side view of a mechanical joint according to an example embodiment of the present invention in a closed position;

FIG. 2b illustrates a side view of a mechanical joint according to an example embodiment of the present invention in an open position;

FIG. 2c illustrates a side view of a mechanical joint according to an example embodiment of the present invention in an intermediate position;

FIG. 3a illustrates a side view of a mechanical joint according to another example embodiment of the present invention in a closed position;

FIG. 3b illustrates a side view of a mechanical joint according to another example embodiment of the present invention in an open position;

FIG. 3c illustrates a side view of a mechanical joint according to another example embodiment of the present invention in an intermediate position;

FIG. 4a illustrates a side view of a mechanical joint according to another example embodiment of the present invention in a closed position;

FIG. 4b illustrates a side view of a mechanical joint according to another example embodiment of the present invention in an open position;

FIG. 4c illustrates a side view of a mechanical joint according to another example embodiment of the present invention in an intermediate position;

FIG. 5 illustrates an example apparatus according to an embodiment of the present invention.

### DETAILED DESCRIPTION OF THE DRAWINGS

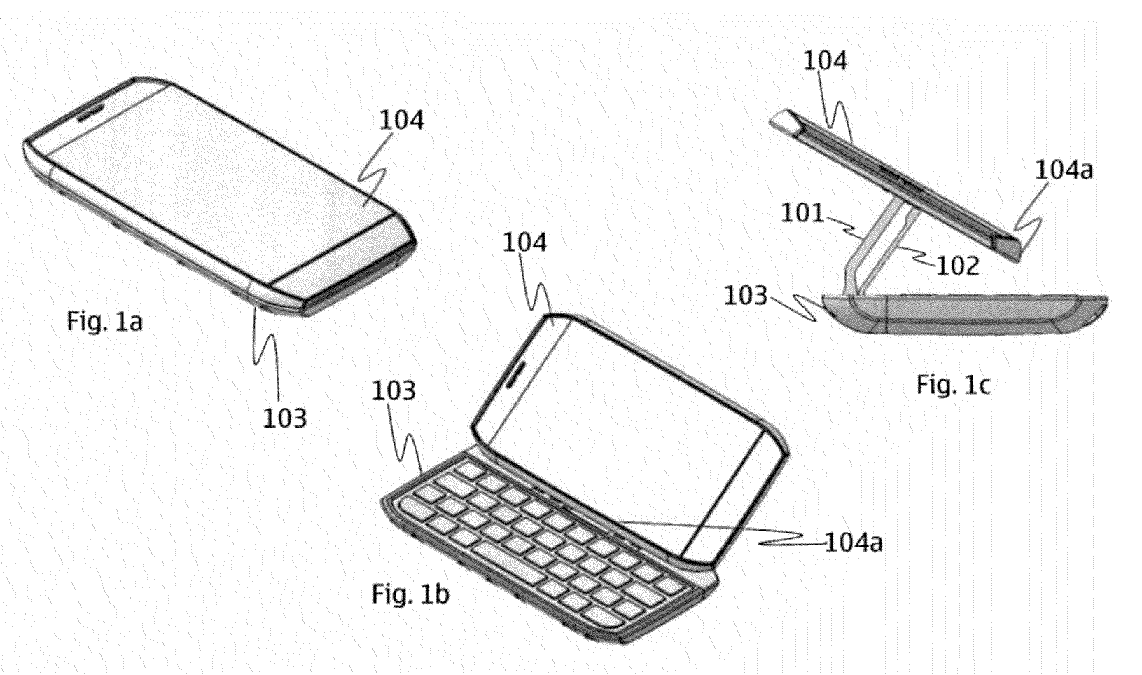

An example embodiment of the present invention and its potential advantages and effects are illustrated by referring to FIGS. 1 through 5 of the drawings. Embodiments may relate to an apparatus having an open and a closed position such that the upper user interface, for example a display, is accessible, viewable and/or usable in the both open and closed positions.

FIG. 1a illustrates an example of a two part apparatus according to an embodiment of the present invention in a closed position. The apparatus according to the embodiment comprises two portions referred here as a lid portion 104 and a base portion 103. The two portions form a compact construction, when the apparatus is in a closed position. In this embodiment the surfaces are substantially similar size and thus substantially cover each others in the closed position. In FIG. 1a the lid portion 104 is on top of the base portion 103 of the apparatus such that one surface of the lid portion 104 is towards one surface of the base portion 103. User interface of the lid portion 104 is faced openly upwards, thus accessible to a user. In example embodiments the user interface of the lid portion 104 may comprise one or more function, feature, action, block, duty or operational entity, which may be used in the closed position of the apparatus. In the example of the FIG. 1a, the lid portion 104 comprises a display. The display may be a touch display enabling input and output functions among others. According to other example embodiments, the lid portion may include other blocks, features or functions, instead or in addition. For example, the lid portion may comprise buttons in addition to a display, to enable a user interface when using non-touch display.

FIG. 1b illustrates an example of a two part apparatus according to an embodiment of the present invention in an open position. A lid portion 104 and a base portion 103 may substantially correspond to those illustrated in FIG. 1a. In the open position the lid portion 104 has been moved away from the base portion 103, thus revealing the base portion 103. A border side 104a of the lid portion 104 is placed towards the functional face of the base portion 103. In other embodiments, in an open position, a border side of the lid portion 104a may be placed next to a border side of the base portion 103. The portions may be in contact, or there may be a gap, for example, in the order of millimeters or less, in between them in the open position. In the open position, the apparatus is typically in its widest appearance, making all or most of its functions at least partly available. The user interface of the lid portion 104 is accessible and may be used in the open position. In the open position a full keyboard comprised in a base portion 103 is at least partly revealed for use in the example of FIG. 1b. The base portion 103 and its functions, which are at least partly made available, accessible and/or usable in the open position, may comprise a display, a keyboard, a function key, a soft key, or any other block, part or function of the apparatus. In the open position, the user interface provided on one face of the lid portion 104 and the user interface provided on one face of the base portion 103 may viewable from the same direction. The user interfaces of both portions may be facing substantially the same direction, for example towards a user. An angle between the portions may be, from 90 to 180 degrees, for example. Also other angular positions are possible depending on the desired use, use position and/or used applications. The opposite surfaces of the lid and base portions form a backside of the apparatus in the open position of FIG. 1b, and may comprise no user interface. The backside of the lid and base portion becomes usable or accessible, if the apparatus in the open position is turned or rotated.

FIG. 1c illustrates a side view of an example two part apparatus according to an embodiment of the present invention in an intermediate position. A lid portion 104 and a base portion 103 may substantially correspond to those illustrated in FIG. 1a. In the embodiment of FIG. 1c the apparatus is not fully open, nor fully closed, but in between an open position such as that illustrated in FIG. 1b and a closed position such as that illustrated in FIG. 1a. Lid portion 104 is moved away from the base portion 103 of the apparatus such that the user interface on the upper, visible surface of the lid portion 104, which is accessible in the both open and closed position, maintains its direction, for example facing a user, in the illustrated position. The portions 103, 104 are configured to be movably connected to each other via a joint mechanism. The example embodiment of FIG. 1c illustrates two parts of the joint mechanism comprising two arms, referred here as a main arm 101 and a control arm 102. The joint mechanism is configured to enable controlled movement of the lid portion 104 in relation to the base portion 103 of the apparatus. The joint mechanism is configured to control an angle between the lid portion 104 and the base portion 103, and the distance between the base portion 103 and a border side of the lid portion 104a. The border side of the lid portion 104a may be placed towards and along the accessible surface of the base portion 103, when the apparatus is in an open position. The portions may be in contact to each other, or there may be a gap in between the portions in the open position. The gap may be of magnitude of millimeters or less. The distance between the base portion 103 and a border of the lid portion 104a may be different in open, closed and any intermediate positions. An effect of a controllable distance between the base portion 103 and the lid portion 104 may be providing compact positions, not requiring much space between the apparatus portions in one or any of the positions.

According to embodiments, the opening mechanism is such that the upper part of the lid portion 104, which is accessible in the closed position of FIG. 1a, is also accessible in open position such as illustrated in FIG. 1b. As illustrated in the example embodiment of FIG. 1c, the joint mechanism is connected to the surface opposing the user interface of the lid part 104.

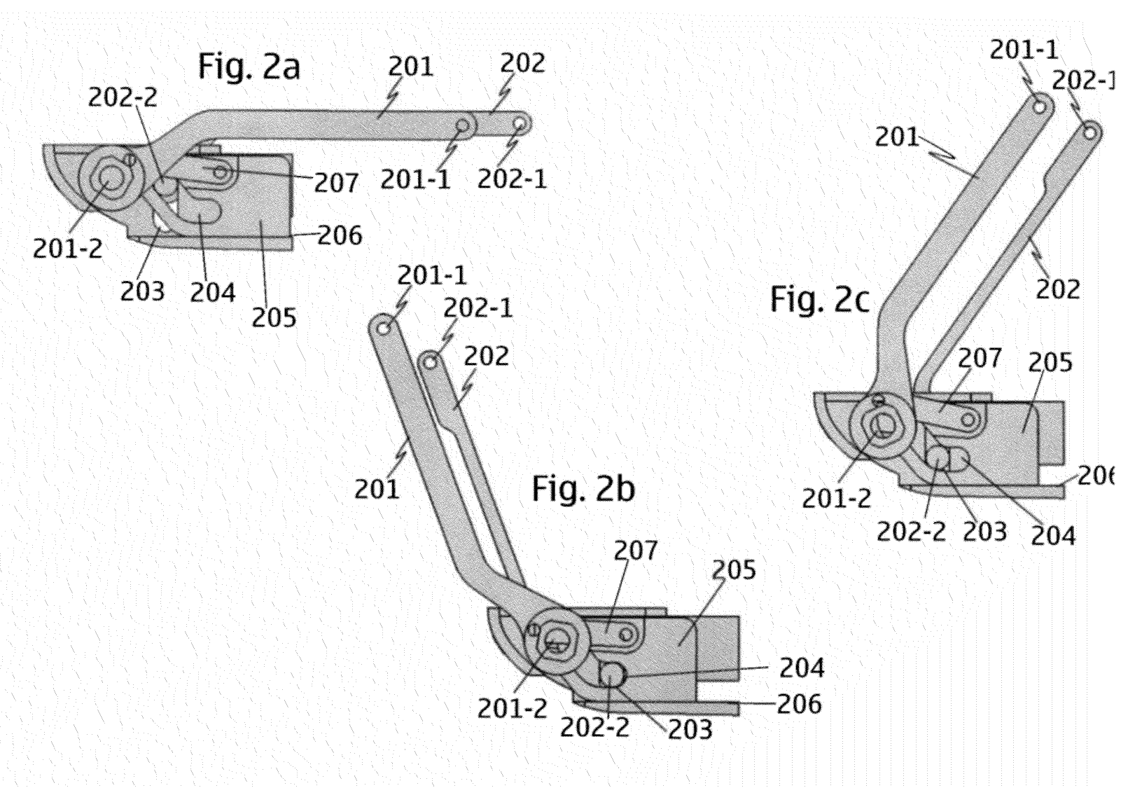

FIG. 2a illustrates a side view of a joint mechanism according to an example embodiment of the present invention in a closed position. A mechanical joint mechanism of the illustrated embodiment is configured to join two parts of an apparatus. The mechanical joint comprises a main arm 201 shown in elongated side view in the example of FIG. 2a. The main arm 201 comprises connection points 201-1, 201-2 in its end portions. A connection portion 201-1 may form a stable pivot point when configured to be connected to one part of an apparatus, for example a lid part. A connection portion 201-2 on other end part of the main arm 201 may form a stable pivot point 201-2 when configured to be connected to another part of the apparatus, for example a base part. Pivot points 201-1, 201-2 enable the connectable apparatus parts to be rotatably movable in relation to the main arm 201. Main arm 201 is rotatable around its pivot points 201-1, 201-2. As the main arm 201 is rotatably moved between an open and a closed portion, an opening angle of the main arm changes 201. The opening angle may be defined, for example, between the main arm 201 and a base part of the apparatus.

The mechanical joint in FIG. 2a, further comprises a control arm 202. The control arm 202 comprises connection points at its end portions. The connection point 202-1 may from a stable pivot point 202-1 when configured to be connectable to one part of an apparatus, for example a lid part. A connection portion 202-2 on other end part of the control arm 202 may form a movable pivot point 202-2 when configured to be connected to another part of the apparatus, for example a base part. The position of the movable pivot point 202-2 may depend on the opening angle of the main arm 201. There may be a connection mechanism configured to connect the main arm and the movable pivot point. The connection mechanism may be determined to control and/or align and/or synchronize the movement of the movable pivot point in accordance to the movement of the main arm.

The connection mechanism of FIGS. 2a, 2b, 2c comprises at least one groove. The movable pivot point 202-2 is configured to move along certain controlled, pre-determined path. The movable pivot point 202-2 is configured to move along a groove 203. A movement path of the movable pivot point 202-2 may be determined by groove 203. The movable pivot point 202-2 may move in or along a groove 203. The groove may be formed by a separate part, or it may be formed integrally by the apparatus portion, to which the joint mechanism is configured to be connected. The groove 203 is configured to form a path of movement for the movable pivot point 202-2. The movable pivot point 202-2 is configured to move along degree and direction determined by the groove 203. The groove 203 may be configured to limit path of the movable pivot point at least partly. The groove 203 may be dimensioned for the path of movement of the movable pivot point. In FIG. 2a the groove 203 is in a form of letter I. In this example embodiment, the movable pivot point 202-2 is configured to move up and down along the groove 203, in a direction of the apparatus portion thickness and/or in a direction perpendicular to the apparatus base part surface. In one example the groove may form an inclined letter I, and then direction of the movement may be in a certain angle towards the apparatus surface. In the closed position of FIG. 2a, the movable pivot point 202-2 is at upper part of the the groove 203. In one intermediate position as in example of FIG. 2c pivot point 202-2 is at lower end part of the groove 203. The position of the movable pivot point in groove 203 may change according to opening angle of the main arm.

The connection mechanism illustrated in FIGS. 2a, 2b, 2c comprises another groove 204 for controlling and/or guiding the movement of the movable pivot point 202-2. The groove 204 has a form of rounded and tilted letter L in this example. In the closed position of FIG. 2a, the movable pivot point 202-2 is at one end portion of the groove 204. The other extreme position, being the other end of the groove 204 in this example, is achieved by the pivot point 202-2, when the apparatus is in the open position as illustrated in FIG. 2b. The groove 204 is used to control the movement of the movable pivot point 202-2, and thereby the control arm 202, according to movement of the main arm 201. The groove 204 is formed by a slider part 205, which is configured to slide along a rail or a slit 206 along a surface of an apparatus portion, for example a side surface. The slider part 205 is connected to the main arm 201 using a connecting portion 207. The main arm 201 movement is induced to the slider part 205 via the connecting portion 207. The slider part 205, or a groove 204 formed by it, is configured to control movement of the movable pivot point 202-2 in accordance to the movement of the main arm 201.

The movement of the movable pivot point 202-2 is controlled in accordance to the movement of the main arm by a connection mechanism. The connection mechanism in this example embodiment comprises two grooves 203 and 204. The form of a groove may have any suitable shape depending on the desired movement of the movable pivot point 202-2. A groove may be straight, rounded, tilted, inclined or curved, and/or have form of J, L, semi-circle, C, or any other suitable. A form of groove may be configured to enable, control and/or guide the movement of a movable pivot point.

In the closed position of the apparatus, the two body parts of the apparatus are parallel, the surfaces facing each others, and the mechanical joint in the embodiment of FIG. 2a, is placed in between, or partially contained within, the facing surfaces of the body parts. The control arm 202 is substantially parallel with the main arm 201 in the closed position of FIG. 2a. This may have an effect of providing a compact construction for an apparatus in a closed position. In the closed position of FIG. 2a, the control arm 202 extends further than the main arm 201.

FIG. 2b illustrates a side view of a mechanical joint according to an example embodiment of the present invention in an open position. Stable pivot point 201-1 of the main arm 201 and the stable pivot point 202-1 of the control arm 202 may receive a lid portion of an apparatus, for example. The stable pivot point 201-2 of the main arm 201 and the movable pivot point 202-2 of the control arm 202 may receive a base portion of an apparatus, correspondingly. When the attachable apparatus is in an open position, the position of the joint mechanism is as illustrated in a FIG. 2b. The movable pivot point 202-2 may be one extreme position in its degree of freedom of movement as determined by the grooves 203 and 204. In this example the L-shaped groove 204 is positioned according to position of the main arm 201. The slider part 205 comprising the groove 204 is moved according to movement of the main arm 201. The slider 205 and the main arm 201 are connected via a connecting portion 207. Opening of the attachable lid portion is illustrated in FIG. 1c. Adjusting the position of the movable pivot point 202-2 enables adjusting a distance between the lid, or a border side of the lid 104a, and base portions of the apparatus. The distance may be adjusted in open position and/or during opening, at any intermediate position. In accordance with an embodiment the distance adjustment is related to the opening angle. In one example, the opening angle of the apparatus is determined by movement of the main arm having two stable pivot points. The distance between the apparatus parts from each others is controlled by a control arm in accordance with the opening angle.

FIG. 2c illustrates a side view of a mechanical joint according to an example embodiment of the present invention in an intermediate position. A base part and a lid part of an apparatus are configured to be connected by the main arm 201 and the control arm 202 such that the pivot points 201-1 and 202-1 are configured to connect to the lid part of an apparatus and the pivot points 201-2 and 202-2 are configured to connect to the base part of an apparatus. The distance between the body part and the lid part formed by the main arm 201 is constant. The distance between the body part and the lid part formed by the control arm 202 is configured to vary. The distance between the body part and the lid part of an apparatus formed by the control arm 202 may depend on the current position of the joint mechanism, or an apparatus attached thereto. Distance between the body part and a border side of a lid part along the control arm 202 may have be in its shortest form in one intermediate position of an apparatus as shown in FIG. 2c. In another example embodiment it may be just the opposite. Geometry of the joint mechanism may depend on the wanted end result, for example at least one of, but not limited to: what viewing angle is desired, what shall be the height of the lid portion in relation to the base portion, what is the desired opening angle in an open position, what is the opening path or alike. In the intermediate position of FIG. 2c, the distance of the apparatus parts along the control arm 202 may change according to the opening angle of the apparatus, which is dependent on the movement of the main arm 201. At any intermediate position, during change between the extreme open or closed positions, the distance between the base and the lid along the control arm 202 may change, or be adjusted. In the embodiment of FIGS. 2a, 2b, 2c the movement of the movable pivot point 202-2 is controlled in accordance to the movement of the main arm 201. Movable pivot point 202-2 is configured to adjust distance between a base portion and a lid portion of an apparatus configured to be attached to the joint mechanism according to embodiments of the invention. The distance between the apparatuses base and lid portions may be adjusted in accordance with the opening angle between the apparatus portions.

The movement of a body part of an apparatus is dependent on the movement of a movable pivot point in the FIGS. 2a, 2b, 2c. In prior solutions for example joint mechanisms having two arms have been presented. However, the prior joint mechanisms have comprised for example only fixed, stable pivot points. An effect of a movable pivot point may comprise controlling movement of the parts of a two part apparatus. An effect of an adjustable distance between the apparatus portions may comprise needing less space in intermediate positions, for example during opening and/or closing the apparatus.

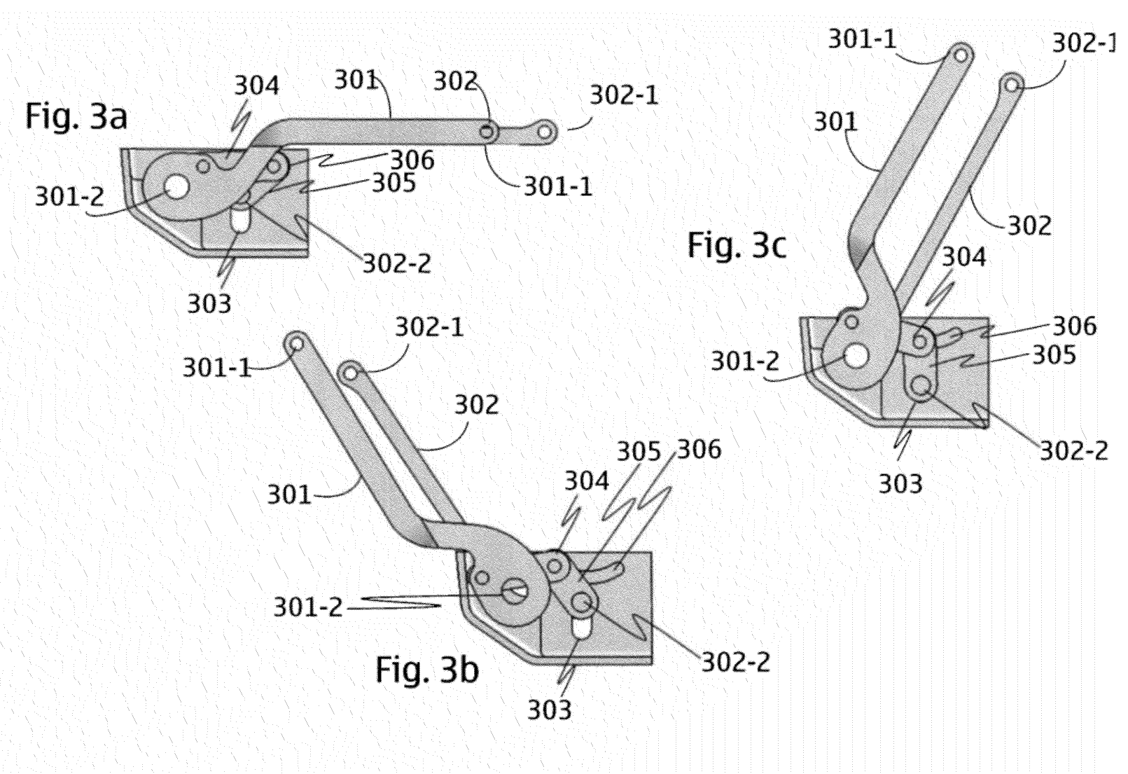

Embodiments of FIGS. 3a, 3b, 3c illustrate an example embodiment of the present invention comprising a joint mechanism. FIG. 3a illustrates a side view of a mechanical joint according to another example embodiment of the present invention in a closed position. Movement of the movable pivot point 302-2 is synchronized or aligned with the movement of the main arm 301 by a connection mechanism. The connection mechanism comprises two link arms 304, 305 configured to control movement of a movable pivot point 302-2 of the control arm 302. The connection mechanism further comprises two grooves or slots 303, 306 in the example embodiments of FIGS. 3a, 3b, 3c. One end of the link arm 305, which is connected to the link arm 304, is arranged to move along a groove 306. The link arm 304, connected thereto, move correspondingly. The other end of the link arm 305 is arranged to move in a groove 303. The movable pivot point 302-2 is at one of its two extreme positions, when the connection point of the link arms 304, 305 is on one end of the groove 306. The other end of the link arm 305 is arranged to be in the bottom end position of the groove 303 in the intermediate position, as shown in FIG. 3c. In other embodiments the positions of arms may differ in accordance to geometry of movement and/or geometry of arms and/or the construction of the joint mechanism. The link arm 304 is configured to be movably connected to the main arm 301. The link arms 304 or 305 comprise an elongated arm and pivot points at its ends. In the example embodiments of FIGS. 3a, 3b, 3c the elongated arms 304, 305 are rotatably movable around the pivot point connecting the two. In the closed position of FIG. 3a the elongated arms 304, 305 are close to each other. The angle between the elongated arms is small, for example below 30 degrees. The link arms 304, 305 may be in a compact form in a closed position.

FIG. 3b illustrates a side view of a mechanical joint according to an example embodiment of the present invention in an open position. In this example of the open position the movable pivot point 302-2 is at another of its two extreme positions. The pivot points of the control arms 304, 305 are on another end of the grooves 306, 303 respectively, being different from the end position of the closed position of FIG. 3a. The movement of the movable pivot point 302-2 is synchronized or aligned with the movement of the main arm 301 using a link arm 304, which is configured to be movably connected to the main arm 301. In the open position of FIG. 3b the elongated link arms 304, 305 are away from each other. The angle between the link arms 304, 305 is wide, for example from 45 to 90 degrees. The link arms 304, 305 are in wide, open form.

FIG. 3c illustrates a side view of a mechanical joint according to an example embodiment of the present invention in an intermediate position. The main arm 301 and the control arm 302 are in one of their intermediate position between the two extreme positions being the closed position of FIG. 3a and the open position of FIG. 3b. In the intermediate position of FIG. 3c the movable pivot point the link arm 305 is in one of its two extreme end positions in the groove 303. The link arm 304 is in the intermediate of its two extreme positions in the groove 306. The angle between the elongated link arms 304, 305 may be between the angle as in the closed position of FIG. 3a and the angle as in the open position of FIG. 3b. However, the positions of arms or pivot points and are not restricted to ones shown in any of the example embodiments. When the main arm is at the intermediate point of its path of movement, the other arms or portions of the joint mechanism may not be in the intermediate points of their paths of movements. The other arms or portions may move more or less, or at some point slower or faster, than the main arm. The movement of joint mechanism portions may depend on mechanical construction, chosen geometry of arms and/or wanted opening movement of the attachable apparatus. An open position, for example position and angle between the apparatus parts in the open position, may effect the movement of the parts of the joint mechanism or its arms at the end of the opening. At the end of the opening, when the apparatus is not yet fully open, rotation of the main arm may be added or speeded up, while change of angle of the lid may be restrained or slowed down. The desired movements may be implemented or adjusted by using certain construction and details of the joint mechanism.

A base part and a lid part of an apparatus may be connected to the main arm 301 and the control arm 302 as in the example embodiment of FIGS. 2a, 2b, 2c. The distance between the body part and the lid part formed by the main arm 301 is constant. The distance between the body part and a border side of the lid part formed by the control arm 302 may be configured to vary. The distance between the body part and a border side of the the lid part of an apparatus formed by the control arm 302 may depend on the current position of the apparatus (or joint mechanism), and/or the angle between the body and lid parts. In example embodiments the distance may vary depending on the wanted construction and its usability or applicability on desired circumstances. In some embodiments at any intermediate position, during change between the extreme open or closed positions, the distance between the base and border of the lid along the control arm is adjusted according to the opening angle. In this example embodiment movement of the movable pivot point 302-2 is controlled in accordance to the movement of the main arm 301. Movable pivot point 302-2 is configured to adjust distance between a base portion and a border side of a lid portion configured to be attached to the joint mechanism according to all or certain embodiments.

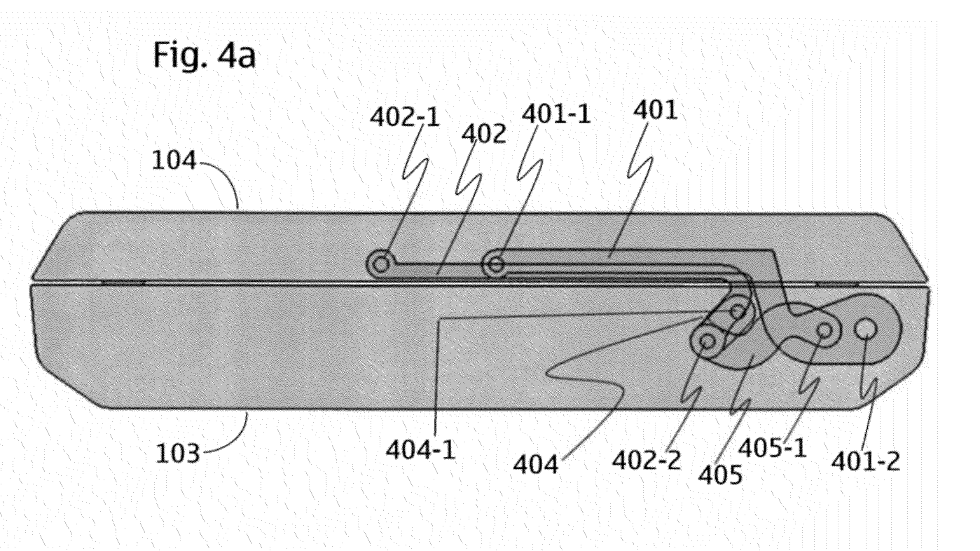

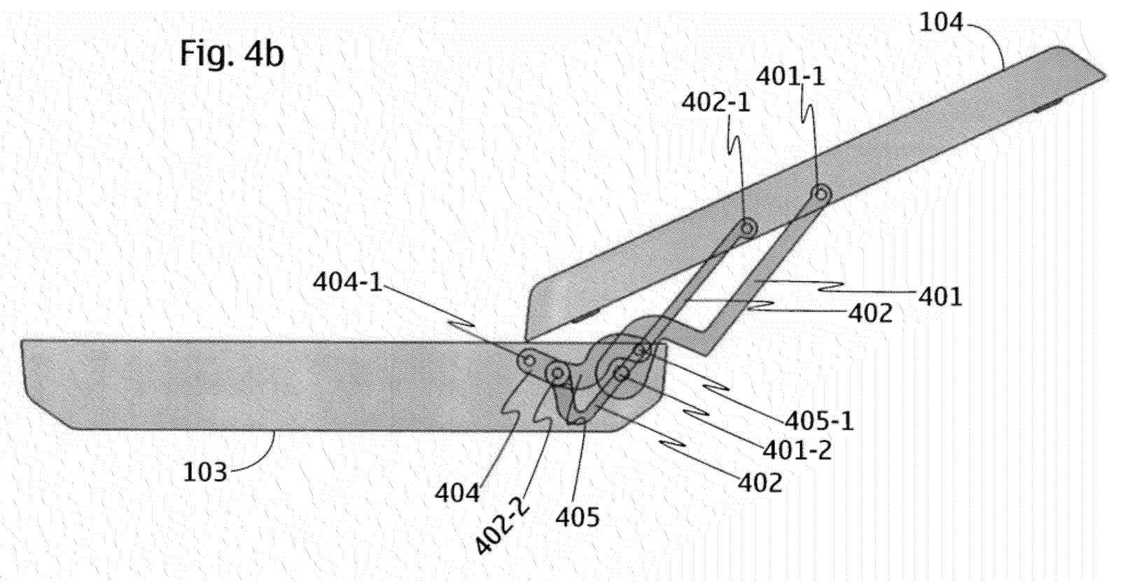

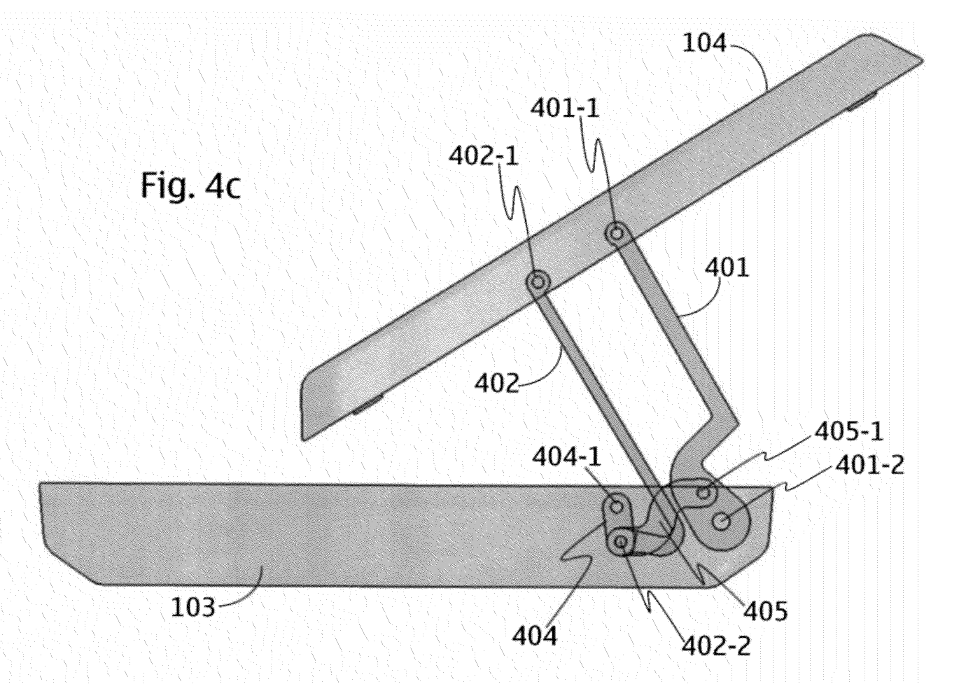

FIGS. 4a, 4b, 4c illustrate another example embodiment of the present invention. The apparatus of FIGS. 4a, 4b, 4c comprises two body portions 103, 104. FIG. 4a illustrates the apparatus in a closed position, FIG. 4b in the open position, and FIG. 4c in an intermediate position, being between the closed position of FIG. 4a and the open position of FIG. 4b. A joint mechanism in FIGS. 4a, 4b, 4c comprises a main arm 401 and a control arm 402. Movement and/or path of a movable pivot point 402-2 of the control arm 402 is controlled by a connection mechanism comprising arms. The arms are referred here as a pull arm 405 and a sector arm 404. One end of the pull arm 405-1 is fixed to the main arm. The pull arm 405 thus conforms with the movement of the main arm. The other end of the pull arm 405 is fixed to the movable pivot point or end of the control arm 402-2. The movement of the movable pivot 402-2 is controlled by a sector arm 404. One end of the sector arm is fixed to the movable pivot point of the control arm 402-2 along with the one end of the pull arm 405. The other end of the sector arm 404-1 is fixed, for example to the base portion of the apparatus as illustrated in FIGS. 4a, 4b, 4c. In this embodiment, the movement is controlled using an s-shaped pull arm 405, which is attached to the movable pivot point 402-2 and to the sector arm 404. Movement of the movable pivot point 402-2 may be provided and designed by path of the sector arm 404. The pull arm 405 may participate in moving the movable pivot point 402-2 along a path determined by the sector arm 404. The pull arm 405 is configured to be movably connected to the main arm 401. In the embodiment the pull arm 405 and the sector arm 404 are rotatably movable around the pivot point connecting them. Further their connection point comprises rotatably movable pivot point 402-2 in this embodiment.

A base part 103 and a lid part 104 of an apparatus are configured to be connected to the main arm 401 and the control arm 402. The distance between the body part and the lid part formed by the main arm 401 is constant. The distance between the body part and the lid part formed by the control arm 402 may be configured to vary due to the movable pivot point. The distance between the body part and the lid part of an apparatus formed by the control arm 402 may depend on the current position of the apparatus (or joint mechanism), and/or the angle between the body and lid parts. At any intermediate position, during change between the extreme open or closed positions, the distance between the base 103 and the lid 104, or border side of the lid 104a, along the control arm 402 may be adjusted according to an opening angle. The movement of the movable pivot point 402-2 is synchronized or aligned with the movement of the main arm 401 by a connection mechanism comprising arms in this example embodiment. Movable pivot point 402-2 is configured to adjust distance between the base portion 103 and border side of the lid portion 104a of an apparatus configured to be attached to the joint mechanism according to all or certain embodiments.

In some embodiments the joint mechanism comprises two arms having pivot points at their both ends. According to all or some of the embodiments, the movable pivot point may be at any of the pivot points of the joint mechanism. The place of the movable pivot point may be chosen as convenient for the current embodiment, desired use, application or construction. Further, a joint mechanism may comprise multiple movable pivot points according to embodiments of the present invention.

According to example embodiments the joint mechanism may comprise an arm having a shape other than straight, comprising, but not limited to, curved shape, S-shape, J-shape, oval shape, and any other suitable shape. The shape of an arm may relate to construction to the attachable apparatus. The shape(s) of arm(s) may be designed to fit the arms to a desired apparatus construction, or to be fitted inside an apparatus construction, or to allow wanted movement or positions of the apparatus, or to enable certain apparatus construction without compromises to other apparatus block or blocks. Number of arms may not be limited to two. In example embodiments a pivot point may be in an other portion of an arm than end portion. For example, the arm may comprise an additional pivot point in between the end portions of the arms, the additional pivot point configured to for example receive an extra portion of an apparatus. In case of apparatus body parts, there may be for example additional display, or layer for a display, for example screening or sheltering the display, or additional user interface portion, or a body shelter, formed by an extra pivot point integrated to the joining mechanism, or in addition to it.

Synchronization or aligning the movement of the movable pivot point with the movement of the main arm may be implemented using a connection mechanism. The connection mechanism may comprise at least one of groove, slot, track, channel, arm, link arm, shaped arm, or any other connecting and/or guiding means. Aligning movement may comprise synchronizing movement. The connection mechanism may be used to connect the main arm and the movable pivot point via other parts. By controlling the movement of the movable pivot point a desired opening area may be achieved. Other effects of the controlled movement of the movable pivot point may be desired movement, for example a certain degree to a first direction and certain degree to another direction, which may be perpendicular to the first direction. Controlled movement may enable desired movement speed to be achieved. In addition or alternatively a viewing angle may be adjusted. Several viewing angles may be adjusted depending on the shape of the groove enabling two or more angles of the joined body parts in the open position. The groove may comprise several notches for receiving a movable pivot point, where each of the notches provides a fixed position for a body part such that the angle between the body parts may be changed by choosing another notch for the movable pivot point. According to an example embodiment, the fixed, stable placements of the movable pivot point along its path of movement may be realized with magnets. Magnets may be comprised in a pivot point and in certain places of a groove, thereby fixing certain locations for the movable pivot point.

In example prior art solutions distance between opening apparatus portions is fixed. In solutions, where the same upper display is usable both in open and closed position of the apparatus, distance between a base portion and opening lid may become long. This may have negative influence on user experience. Portions may temporarily get far apart from each other during opening. The otherwise rather compact apparatus may need unexpected space during opening or closing in prior art examples. According to example embodiments of the current invention, the gap between the apparatus portions in the intermediate and/or open position of the apparatus, may be decreased or close to zero via movement adjustment or control. In an open position this may have an effect to enhance usability and/or visibility and/or user interface of an apparatus. Another effect of one or more embodiments may be not blocking user interface area in the open position, but achieving an enlarged area. Another effect may be wider opening angle of an apparatus. Embodiments may comprise an adjustable distance between apparatus portions, which distance may be at its shortest form or shape at the intermediate position. Example solutions of prior art comprise fixed arms, which may require more space in between the extreme positions. Also fixed arms of prior art may require more space at least in the extreme positions, whereas the embodiments of the invention may have compact structure. The construction of the joint mechanism may be compact in the closed position, where the arms may be substantially parallel and in a close proximity to each other or within each other, for example.

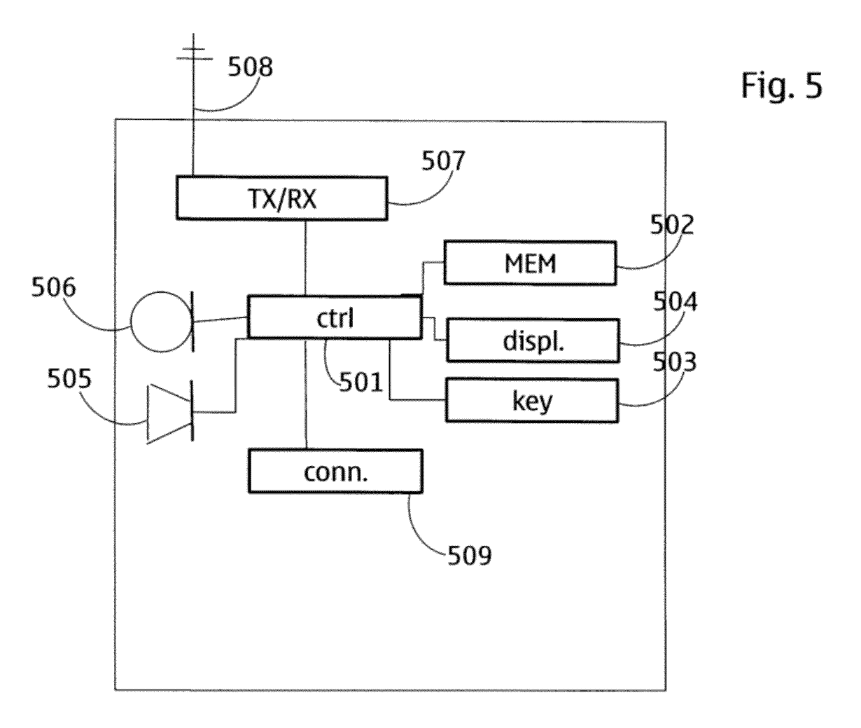

FIG. 5 illustrates an example apparatus according to an embodiment of the present invention. The apparatus comprises a processor 501 configured to process and/or execute digital data, for example instructions or program code. The processor 501 may be a control process unit, CPU, a master control unit, MCU, a microprocessor, a digital signal processor, DSP, an application specific intergrated circuit, ASIC, a field programmable gate array, FPGA, a microcontroller, or any suitable combination of the previous or alike processor. The processor 501 may receive and transmit processed data, raw data or data to be processed to/from a memory 502, for example. The memory 501 may comprise any suitable structure or combination of memory types, like read-, write-, volatile-, or non-volatile memory. The memory 502 may comprise one memory block, shared memory blocks, or multiple different or similar kinds of memory blocks. The example apparatus of FIG. 5 comprises blocks configured to form a user interface, configured to enable user interaction. A user interface may comprise an input block 503, which can be at least one of a key, a keyboard, a touch input, a mouse, a stylus or any other input apparatus. A user interface may comprise an output block 504, which can be for example a display, or any other mean or combination of means enabling presentation of information comprising for example visual-, audio-, or multimedia data.

A display in the embodiments of the present invention may be any kind of available and suitable display. Example display technologies are thin film transistor, TFT, cathode ray tube, CRT, plasma display panel, PDP, liquid crystal display, LCD, digital light processing, DLP, field emission display, FED, surface-conductor electron-emitter display, SED, light emitting diode, LED, organic light emitting diode, OLED, or any other type of display. The displays may be direct view, projection or any other kind of display. Further, for example, microelectromechanical systems, MEMS, based apparatuses, like interferometric modulator, iMoD, displays may be utilized. In the example embodiments the display may be a touch display, a multitouch display, or alike. The display may be used as an input 503 and/or as an output 504 apparatus.

The example apparatus of FIG. 5 comprises a speaker 505 for outputting audio data of any suitable type and microphone 506 for inputting audio data of any suitable type. Other example apparatuses may include other block enabling audio formation, input, output and saving. The audio of the apparatus may comprise anything from a monotonic, buzzer sounds to more sophisticated players of stereo sound recordings, or any other audio device. The example apparatus of FIG. 5 further comprises transmission branch 507 configured to enable communication via at least one network. The transmission branch 507 may be configured to enable transceiving and receiving of data via antenna 508 to/from the network. The transmission branch 507 may comprise a radio interface. The radio interface may be Wireless Local Area Network, WLAN, Bluetooth, Global System for Mobile Communications, GSM, General Packet Radio Service, GPRS, Code Division Multiple Access, CDMA, Wideband Code Division Multiple Access, WCDMA or Long Term Evolution, LTE, for example. Any other suitable communication interface may be utilized.

The apparatus can additionally or alternatively comprise another connection block 509. The connection block 509 may be configured to enable connection to a local network or to any external net or internet. The connection block 509 may be configured for a wireless and/or a wired connection. The wireless connection may comprise for example infrared or Bluetooth connection. The wired connection may comprise a cable connector, for example universal serial bus (USB) connector. FIG. 5 illustrates one example only and it is clear that embodiments of the present invention can be implemented in different kind of apparatuses embodying only part of the illustrated apparatus blocks, and/or comprising other available apparatus blocks in addition or instead.

Embodiments of the present invention may be implemented in an apparatus comprising at least two movably joined parts. The apparatus can be for example a laptop, a computer, a mobile phone, a mobile computer, a personal digital assistant, an intelligent digital apparatus, a game apparatus, or any other apparatus comprising at least two body portions, which are movable in relation to each other. Besides a structure, where two body portions are substantially equal in size, the movable portion may be of different size compared to the other portion or portions of the apparatus. The movable portion may be any portion of an apparatus comprising, but not limited to a display, which is movable in relation to a base part of the apparatus; a second display, which is movable in relation to a device body; a camera module, movable in relation to a body part of the apparatus; or any other movable part or block for the apparatus.

A portion, for example a lid part, of an apparatus according to embodiments of the invention may be configured to open and close automatically or semi-automatically. Any automated opening may be implemented for example using a bi-stable spring, where the spring force is induced to the lid part in the intermediate portion. The spring force may then force the lid towards the open position, or to a closed position, whichever it closer to the current position. Another implementation example is a spring forcing the apparatus to the open position. The closed position may be fixed using a latch, for example, and opened using an opening button releasing the latch. When the latch is released, the lid opens due to the spring force. In this embodiment the user shall overcome the springback factor in order to re-enter the closed position of the apparatus. In another implementation example automatization may be implemented using an electronic motor. In one possible embodiment a lid portion may slide certain amount. During the sliding the spring force is released and the released spring force may push the lid towards the open position.

According to embodiments the joint mechanism may be adjustable in the open position. Adjustment of the joint mechanism, which may comprise rotation, may allow the opening angle of the apparatus portions to be enlarged by, for example a further 30 degrees. This may have effect of enlarging the view angle and/or enhancing usability and/or improving user experience, for example. In accordance to certain embodiments, there may be achieved enlarged user interface in the open position. On certain circumstances, depending at least partly for example on models and chosen parts and interrelationship of them, some further support may be provided to maintain proper usability and stability of the apparatus when on a plane, like on a table. In one embodiment, a further support extends from the base part of an apparatus in the open position. The support may extend from the base portion such that it extends the base surface on a table, on which the apparatus is placed on. The further support may compensate for weight and/or position of the lid part in the open position. The support part may be a separate portion comprised in an apparatus or in a joint mechanism. In some embodiments the support part may be part of a slider portion, the slider portion thus forming both a groove and a support.

According to a further embodiment, the solution may comprise a sliding mechanism, where both arms in both apparatus portions slide. The sliding may be implemented sliding only arm ends attached to a lid portion, or sliding only arm ends attached to a base portion, or in any other suitable way. In one example, when user wants to change position of the apparatus from closed to open, he pushes the lid portion. The lid portion slides away and along the base portion. After the sliding movement, the opening movement raising the lid portion begins. This may have an effect to usability of the apparatus and/or its joint mechanism. The user may get a feedback of correctly initiated force and/or correct direction of force by the sliding movement. User may be attracted to continue towards the actual opening.

Without in any way limiting the scope, interpretation, or application of the claims appearing below, a technical effect of one or more of the example embodiments disclosed herein may be providing an apparatus comprising at least two portions comprising one display accessible and/or usable in both open and closed position of the apparatus. Another technical effect of one or more of the example embodiments disclosed herein may be usability of a lid part functions, for example a display, in both open (wide) and closed (compact) positions of the apparatus. Another technical effect of one or more of the example embodiments disclosed herein may be avoiding need of an extra display. Another technical effect of one or more of the example embodiments disclosed herein may be enabling adjusting distance between apparatus portions in an intermediate position(s) and/or in an open position. Another technical effect of one or more of the example embodiments disclosed herein may be enlarged size of an apparatus in an open position and/or an input area size of an apparatus and/or wide use area in an open position. Another technical effect of one or more of the example embodiments disclosed herein may be enabling use of one display and/or protecting another display, when the apparatus is in a closed position. Another technical effect of one or more of the example embodiments disclosed herein may be usability of a two part apparatus. Another technical effect of one or more of the example embodiments disclosed herein may be adjustability of the distance between the apparatus parts.

If desired, the different functions or features discussed herein may be performed in a different order and/or concurrently with each other. Furthermore, if desired, one or more of the above-described functions may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

1. A joint mechanism, comprising:
a main arm comprising pivot points configured to be connectable to an apparatus; and
a control arm comprising pivot points configured to be connectable to the apparatus;
wherein the pivot points are configured to enable movable connection between moving apparatus parts; and
wherein at least one of the pivot points comprises a movable pivot point

2. A mechanical joint according to claim 1, wherein the main arm and the control arm comprise connection points at their end portions.

3. (canceled)

4. A mechanical joint according to claim 1, wherein the apparatus comprises a user interface configured to be accessible in any opening angle of the joint mechanism.

5. A mechanical joint according to claim 1, wherein a position of the movable pivot point is configured to be adjusted in accordance to the current opening angle of the main arm.

6. A mechanical joint according to claim 1, wherein a movement of the movable pivot point is aligned with the movement of the main arm.

7. A mechanical joint according to claim 1, further comprising a connection mechanism configured to connect the main arm and the movable pivot point.

8. A mechanical joint according to claim 7, wherein the connection mechanism comprises at least one groove configured to control movement of the movable pivot point.

9. A mechanical joint according to claim 7, wherein the connection mechanism comprises at least one arm configured to be in pivotable connection with the main arm and configured to control movement of the movable pivot point.

10. An apparatus comprising:
Two apparatus portions; and
a joint mechanism;
the joint mechanism comprising a main arm and a control arm comprising pivot points;
wherein the main arm and the control arm are configured to be connected to a first apparatus portion at their one pivot points, and to a second apparatus portion at their other pivot points;
wherein the pivot points are configured to enable movable connection between the two apparatus portions; and
wherein at least one of the pivot points comprises a movable pivot point

11. (canceled)

12. An apparatus according to claim 10, wherein current position of the movable pivot point is configured to be adjusted according to the current opening angle of the main arm.

13. An apparatus according to claim 10, wherein the control arm comprises a movable pivot point.

14. An apparatus according to claim 10, wherein a movement of the movable pivot point is aligned with the movement of the main ann.

15. An apparatus according to claim 10, further comprising a connection mechanism configured to connect the main arm and the movable pivot point.

16. An apparatus according to claim 15, wherein the connection mechanism comprises at least one groove configured to control movement of the movable pivot point.

17. An apparatus according to claim 16, wherein the groove is formed by at least one of the first apparatus portion, the second apparatus portion and a separate slider part.

18. An apparatus according to claim 16, wherein the connection mechanism comprises at least one arm configured to be in pivotable connection with the main arm and configured to control movement of the movable pivot point.

19. (canceled)

20. (canceled)

21. A method, comprising:
movably joining a first apparatus portion and a second apparatus portion of an apparatus by a joint mechanism;
wherein the joint mechanism comprises a main arm and a control arm connectable to the first apparatus portion on their one pivot points, and to the second apparatus portion on their other pivot points for enabling movable connection between the first and the second apparatus portions; and
wherein at least one of the pivot points comprises a movable pivot point

22. A method according to claim 21, comprising adjusting current position of the movable pivot point according to the current opening angle of the main arm.

23. (canceled)

24. A method according to claim 21, comprising synchronizing a movement of the movable pivot point with the movement of the main arm.

25. A method according to claim 21, further comprising a connection mechanism configured to connect the main arm and the movable pivot point.

26.-30. (canceled)
